(19) United States
(12) Patent Application Publication
(10) Pub. No.: US 2010/0178620 A1
(43) Pub. Date: Jul. 15, 2010

(54) INVERTED PATTERN FORMING METHOD AND RESIN COMPOSITION

(75) Inventors: Satoshi DEI, Tokyo (JP); Kyoyu Yasuda, Tokyo (JP); Koichi Hasegawa, Tokyo (JP); Fumihiro Toyokawa, Tokyo (JP); Masato Tanaka, Tokyo (JP); Keiji Konno, Tokyo (JP)

Correspondence Address: Ditthavong Mori & Steiner, P.C., 918 Prince Street, Alexandria, VA, 22314, US

(73) Assignee: JSR Corporation, Tokyo (JP)

(21) Appl. No.: 12/624,427

(22) Filed: Nov. 24, 2009

(30) Foreign Application Priority Data
May 21, 2007 (JP) 2007-134493
Oct. 30, 2009 (JP) 2009-249874

(51) Int. Cl. B05D 1/32; G03F 7/20; C09D 183/04

(52) U.S. Cl. 430/325; 427/282; 524/588

(57) ABSTRACT

A method for forming an inverted pattern includes forming a photoresist pattern on a substrate, filling a space formed by the photoresist pattern with a resin composition including a polysiloxane and a solvent, and removing the photoresist pattern to form an inverted pattern. The resin composition includes (A) a polysiloxane obtained by hydrolysis and condensation of two types of hydrolysable silane compounds having a specific structure, and (B) an organic solvent containing an alcohol or ether having a specific structure.

### BACKGROUND OF THE INVENTION

1. Field of the Invention

The present invention relates to a method for forming an inverted pattern and a resin composition.

2. Discussion of the Background

In the manufacture of semiconductor devices or the like, a pattern is formed by processing an organic or inorganic substrate using a pattern-transfer method utilizing a lithography technology, a resist development process, and an etching technology (see, for example, Japanese Patent Application Publication (KOKAI) No. 2002-110510).

However, along with an increase in the degree of integration of semiconductor devices formed on a circuit board, a photoresist pattern formed on a substrate has been miniaturized, and the volume of the space defined by the photoresist pattern has decreased. Therefore, it has become difficult to fill the space defined by a resist pattern formed on a substrate with an inverted pattern forming material used for a related-art pattern forming method.

For this reason, development of an inverted pattern forming material excelling in filling properties has been desired. The inverted pattern forming material must not mix with a photoresist pattern formed on a substrate, and must have excellent dry etching resistance and storage stability. However, no specific materials have yet been proposed.

### SUMMARY OF THE INVENTION

The present invention provides a method for forming an inverted pattern including (1) forming a photoresist pattern on a substrate (hereinafter referred to as “step (1)”), (2) filling a space formed by the photoresist pattern with a resin composition including a polysiloxane and an organic solvent (hereinafter referred to as “step (2)”), and (3) removing the photoresist pattern to form an inverted pattern (hereinafter referred to as “step (3)”),

the resin composition including (A) a polysiloxane (hereinafter may be referred to as “polysiloxane (A)”) obtained by hydrolysis and condensation of a hydrolysable silane compound shown by the following formula (1) (hereinafter may be referred to as “compound (1)”) and a hydrolysable silane compound shown by the following formula (2) (hereinafter may be referred to as “compound (2)”) and (B) an organic solvent (hereinafter may be referred to as “solvent (B)”),

RₐSiX₄₋ₐ (1)

wherein R represents a hydrogen atom, a fluorine atom, a linear or branched alkyl group having 1 to 5 carbon atoms, a cyano group, a cyanoalkyl group, an alkylcarbonyloxy group, an alkenyl group, or an aryl group, X represents a halogen atom or —OR¹ (wherein R¹ represents a monovalent organic group), and a represents an integer from 1 to 3, provided that if a is 2 or 3, the plural R may be either same or different and if 4-a is two or more, the plural X may be either same or different,

SiX₄ (2)

wherein X is the same as defined for the formula (1).

In the method of the present invention, the organic solvent (B) preferably includes a compound shown by the following formula (3) (hereinafter may be referred to as “compound (3)”),

R′—O—R″ (3)

wherein R′ represents a linear or branched alkyl group having 1 to 10 carbon atoms and R″ represents a hydrogen atom or a linear or branched alkyl group having 1 to 9 carbon atoms, provided that the total number of carbon atoms contained in R′ and R″ is 4 to 10.

In the method of the present invention, the polysiloxane (A) is preferably obtained by hydrolysis of hydrolysable silane compounds shown by the formulas (1) and (2) in which X represents —OR¹.

In the method of the present invention, the inverted pattern preferably has an Si content and a C content measured by the SIMS method of 30 to 46.7 wt % and 1 to 50 wt %, respectively.

In the method of the present invention, the step (1) may include a resist film forming step of applying a resist composition to the substrate and drying the resist composition (hereinafter referred to “step (1-1)”), an exposure step of applying radiation to a specified area of the resist film (hereinafter referred to as “step (1-2)”), and a development step of developing the exposed areas (hereinafter referred to as “step (1-3)”). The step (1-2) may be carried out two or more times on different areas.

In the method of the present invention, the step (1) may include forming a first resist pattern, and forming a second resist pattern in an area differing from the first resist pattern.

In the step (1), the exposure step (step (1-2)) may be carried out two or more times on different areas after the step (1-1), following which the development step (step (1-3)) may be carried out.

A resin composition of the present invention includes the polysiloxane (A) obtained by hydrolysis and condensation of the compound (1) and the compound (2), and the solvent (B).

In the resin composition of the present invention, the polysiloxane (A) preferably has a polystyrene-reduced weight average molecular weight determined by size exclusion chromatography of 2,000 to 100,000.

It is preferable that the resin composition of the present invention further include (C) a curing promoter.

### BRIEF DESCRIPTION OF THE DRAWINGS

FIG. 1 is a schematic view illustrative of a method of forming an inverted pattern.

### DESCRIPTION OF THE EMBODIMENTS

The present invention will now be described in more detail by way of embodiments.

### [1] Method of Forming Inverted Pattern

In the step (1) of the method for forming an inverted pattern of the present invention, a photoresist pattern (hereinafter referred to simply as “resist pattern”) is formed on a substrate to be processed.

The method of forming the resist pattern is not particularly limited. A general photolithographic process may be used. For example, the following method may be used.

First, as a step (1-1), a resist composition is applied to a substrate and dried to form a photoresist film. Next, as a step (1-2), a selected area of the formed resist film is exposed to radiation through a mask with a specified pattern. After that, as a step (1-3), the exposed area is developed to form a photoresist pattern with a prescribed pattern.

As the substrate, a silicon wafer, an aluminum-coated wafer, or the like may be used. In order to bring out the potential of the later-described resist composition to the maximum extent, it is preferable to previously form an organic or inorganic antireflection film on the substrate, as disclosed in Japanese Examined Patent Publication (KOKOKU) No. 6-12452, for example.

As the resist composition, a composition prepared by dissolving a chemically-amplified resist composition or the like containing an acid generator in a suitable solvent to make a solution with a solid content of 0.1 to 20 mass %, for example, and filtering the solution through a filter having a pore diameter of about 30 nm can be used. A resist composition commercially available as a resist composition for ArF or KrF may be used as is. The resist composition may be either a positive-tone composition or a negative-tone composition.

An appropriate method such as spin coating, cast coating, or roll coating can be used without particular limitations for applying the resist composition.

There are no particular limitations to the method of drying after applying the resist composition. It is possible to vaporize the solvent in the coating by previously heating, for example. The heating temperature is usually about 30 to 200° C., and preferably 50 to 150° C., although the heating conditions may be adjusted according to the composition of the resist composition.

Although not particularly limited, the thickness of the resist film obtained after drying is usually 10 to 1000 nm, and preferably 50 to 500 nm.

As radiation used for exposure, visible rays, ultraviolet rays, deep ultraviolet rays, EUV (extreme ultraviolet), X-rays, charged particle beams, or the like are appropriately selected depending on types of the acid generator included in the resist composition. It is preferable to use deep ultraviolet rays represented by an ArF excimer laser (wavelength: 193 nm) and KrF excimer laser (wavelength: 248 nm). EUV may also be used for forming a micropattern.

The exposure conditions such as a dose of light and the like are appropriately determined depending on the composition of the resist composition, types of additives, and the like.

It is preferable to perform a heat treatment after exposure. This heat treatment ensures a smooth dissociation reaction of the acid-dissociable group contained in the resin components. The heating temperature in this heat treatment is usually about 30 to 200° C., and preferably 50 to 170° C., although the heating conditions may be adjusted according to the composition of the resist composition. The heating temperature is usually 10 to 300 seconds, and preferably 30 to 180 seconds.

As the developer, an alkaline aqueous solution, water, or an organic solvent, and a mixture of these, in which at least one alkaline compound selected from sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, 1,5-diazabicyclo-[4.3.0]-5-nonene, and the like is dissolved can be given. Among these, an alkaline aqueous solution is preferable.

In addition, an appropriate amount of a surfactant and the like may be added to the developer containing the alkaline aqueous solution.

After development using an alkaline aqueous solution developer, the resist film is generally washed with water and dried.

The resist pattern size (for example, a line width in the case of line-and-space, a hole diameter in the case of a hole pattern) obtained in the step (1) is usually 10 to 100 nm. Liquid immersion lithography or the like can be used for forming a micropattern of 10 to 30 nm, for example.

Double patterning, double exposure, or the like may be used in the step (1). Specifically, it is possible to perform the exposure step (1-2) two or more times on different areas.

The above method is broadly classified into two methods. One is a method that includes forming a first resist pattern, and forming a second resist pattern in an area differing from the first resist pattern. Specifically, after forming a first resist pattern by the steps (1-1) to (1-3), a second resist film is formed in the space defined by the first resist pattern, and exposure and development are performed to obtain a second resist pattern (double patterning).

The other method is to perform the exposure step (1-2) several times after the resist film forming step (1-1) on areas differing from the areas on which the step (1-2) has been performed, followed by the development step (step (1-3)) (double exposure).

Miniaturization of both a line-and-space pattern and a hole pattern is possible using the above methods.

In the step (2), the space defined by the resist pattern is filled with the resin composition.

Specifically, the resin composition of an example of the present invention is applied to the substrate on which the above pattern has been formed using an application method such as spin coating, cast coating, or roll coating, whereby the space of the resist pattern is filled with the resin composition. The resin composition according to an example of the present invention used in the step (2) will be described later.

In the step (2), a drying step is preferably provided after filling the space defined by the resist pattern with the resin composition.

Although there are no specific limitations to the drying method, a method of curing, for example, may be used to vaporize the organic solvent in the composition. The heating temperature in the curing is usually about 80 to 250° C., and preferably 80 to 200° C., although the curing conditions may be adjusted according to the composition of the resist composition. When the curing temperature is 80 to 180° C., the later-described planarization can be smoothly performed, particularly planarization using a wet etchback method. The heating time is usually 10 to 300 seconds, and preferably 30 to 180 seconds.

Although not particularly limited, the thickness of the resin film for inverted patterning obtained after drying is usually 10 to 1000 nm, and preferably 50 to 500 nm.

In the above step (3), the photoresist pattern is removed and an inverted pattern is formed.

Specifically, planarization to expose the upper surface of the resist film is first carried out.

Next, the resist pattern is removed by dry etching or dissolution to obtain a target inverted pattern.

An etching method such as dry etchback and wet etchback, a CMP method, and the like can be used for the planarization. Of these, dry etchback using fluorine gas or the like and CMP are preferable. Conditions of the planarization work may be appropriately adjusted without particular limitation.

Dry etching is preferably used for removing a resist pattern. Specifically, oxygen etching, ozone etching, and the like are preferably used. A generally-known resist removing machine such as an oxygen plasma ashing machine and an ozone ashing machine can be used for dry etching.

Conditions of the etching work may be appropriately adjusted without particular limitation.

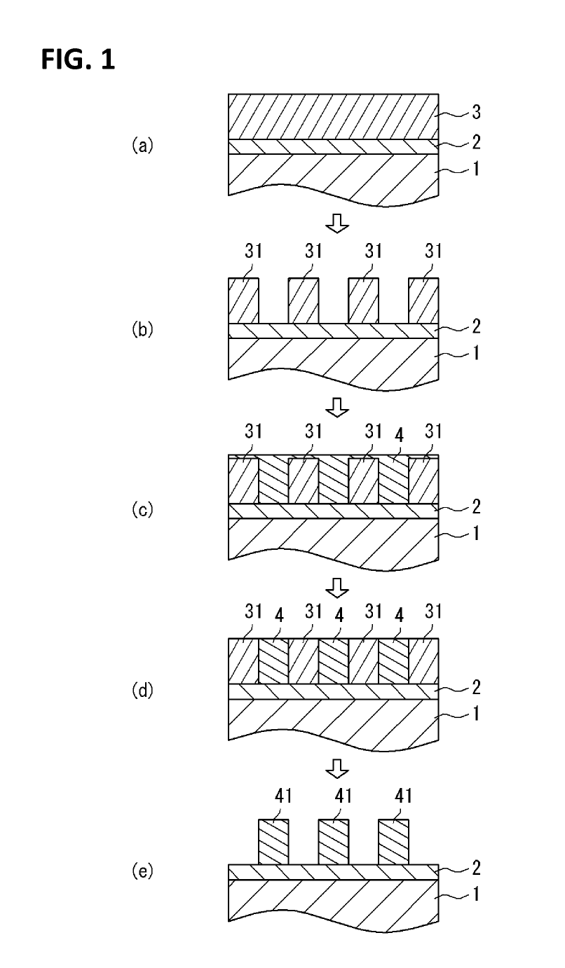

A specific example of the inverted pattern forming method including the above steps (1), (2), and (3) of an example of the present invention will now be explained referring to FIG. 1.

In the step (1), as shown in FIG. 1(a), a resist composition is applied to a substrate 1 which has an antireflection film 2 formed thereon. The applied resist composition is dried by heating or the like to form a resist film 3 having a specified thickness. Next, specified areas of the resist film 3 are exposed to radiation through a mask with a specified pattern. The exposed resist film 3 is developed to form a resist pattern 31 (see FIG. 1(b)).

Next, in the step (2), as shown in FIG. 1(c), a resin composition is applied to the substrate on which the pattern 31 has been formed such that the space of the resist pattern 31 is filled with the resin composition which is dried by heating or the like to form a resin film 4 for pattern inversion.

Next, in the step (3), planarization is carried out using an etchback method, a CMP method, or the like to expose the upper surface of the resist film 31 as shown in FIG. 1(d). Next, the pattern 31 is removed by dry etching to form an inverted pattern 41 (see FIG. 1(e)).

The inverted pattern obtained by the method of an example of the present invention has an elementary composition measured by the SIMS method of Si 30 to 46.7 wt %, preferably 40 to 46.7 wt %, and C 1 to 50 wt %, preferably 1 to 30 wt %. If the Si content is less than 30 wt %, dry etching resistance using a fluorine-containing gas, oxygen gas, or ozone gas may decrease. If it is more than 46.7 wt %, the filling performance of the resist pattern space may decrease. If the C content is less than 1 wt %, the planarization work to expose the upper surface of the resist film by dry etching using a fluorine-containing gas may become difficult. In addition, storage stability may be impaired. If it is more than 50 wt %, oxygen etching resistance and ozone etching resistance may decrease.

For reference, the Si:O:C elementary composition of the polysiloxane obtained by hydrolysis and condensation of the compound (2) is 46.75:53.25:0 wt %.

### [2] Resin Composition

The resin composition according to an example of the present invention includes a polysiloxane (A) and a solvent (B). Such a resin composition is suitably used not only for the method for forming an inverted pattern according to an example of the present invention, but also as an interlayer dielectric material, an antireflection film material, and a planarization material for substrate planarization.

### (1) Polysiloxane (A)

The polysiloxane (A) is obtained by hydrolysis and condensation of at least one compound selected from the compound (1) shown by the formula (1) and the compound (2) shown by the formula (2). Either one compound or two or more compounds among the compounds respectively of the formula (1) or the compounds of the formula (2) may be used.

As examples of alkyl groups having 1 to 5 carbon atoms represented by R in the formula (1), linear alkyl groups such as a methyl group, an ethyl group, an n-propyl group, an n-butyl group, and an n-pentyl group and branched alkyl groups such as an isopropyl group, an isobutyl group, a sec-butyl group, a t-butyl group, and an isoamyl group can be given. One or more hydrogen atoms in these alkyl groups may be substituted with a fluorine atom or the like.

As examples of cyanoalkyl groups, a cyanoethyl group and a cyanopropyl group can be given.

As examples of alkylcarbonyloxy groups, a methylcarbonyloxy group, an ethylcarbonyloxy group, a propylcarbonyloxy group, and a butylcarbonyloxy group can be given.

As an alkenyl group, groups shown by the following formula (1) are preferably given.

CH₂═CH—(CH₂)ₙ—* (i)

wherein n is an integer from 0 to 4 and * indicates a bonding hand.

n in the formula (1) is an integer from 0 to 4, preferably 0 or 1, and more preferably 0 (vinyl group).

As examples of alkenyl groups other than those shown by the formula (1), a butenyl group, a pentenyl group, and a hexenyl group can be given.

As examples of aryl groups, a phenyl group, a naphthyl group, a methylphenyl group, an ethylphenyl group, a chlorophenyl group, a bromophenyl group, and a fluorophenyl group can be given.

X in the formulas (1) and (2) is a halogen atom such as a fluorine atom and a chlorine atom or represents —OR¹. As examples of monovalent organic groups represented by R¹, alkyl groups having 1 to 4 carbon atoms such as a methyl group, an ethyl group, an n-propyl group, an isopropyl group, an n-butyl group, an isobutyl group, a sec-butyl group, and a t-butyl group are preferable. a in the formula (1) is an integer from 1 to 3, and preferably 1 or 2.

Specific examples of the compound (1) shown by the formula (1) include aromatic ring containing trialkoxysilanes such as phenyltrimethoxysilane, benzyltrimethoxysilane, phenethyltrimethoxysilane, 4-methylphenyltrimethoxysilane, 4-ethylphenyltrimethoxysilane, 4-methoxyphenyltrimethoxysilane, 4-phenoxyphenyltrimethoxysilane, 4-hydroxyphenyltrimethoxysilane, 4-aminophenyltrimethoxysilane, 4-dimethylaminophenyltrimethoxysilane, 4-acetylaminophenyltrimethoxysilane, 3-methylphenyltrimethoxysilane, 3-ethylphenyltrimethoxysilane, 3-methoxyphenyltrimethoxysilane, 3-phenoxyphenyltrimethoxysilane, 3-hydroxyphenyltrimethoxysilane, 3-aminophenyltrimethoxysilane, 3-dimethylaminophenyltrimethoxysilane, 3-acetylaminophenyltrimethoxysilane, 2-methylphenyltrimethoxysilane, 2-ethylphenyltrimethoxysilane, 2-methoxyphenyltrimethoxysilane, 2-phenoxyphenyltrimethoxysilane, 2-hydroxyphenyltrimethoxysilane, 2-aminophenyltrimethoxysilane, 2-dimethylaminophenyltrimethoxysilane, 2-acetylaminophenyltrimethoxysilane, 2,4,6-trimethylphenyltrimethoxysilane, 4-methylbenzyltrimethoxysilane, 4-ethylbenzyltrimethoxysilane, 4-methoxybenzyltrimethoxysilane, 4-phenoxybenzyltrimethoxysilane, 4-hydroxybenzyltrimethoxysilane, 4-aminobenzyltrimethoxysilane, 4-dimethylaminobenzyltrimethoxysilane, and 4-acetylaminobenzyltrimethoxysilane; alkyltrialkoxysilanes such as methyltrimethoxysilane, methyltriethoxysilane, methyltri-n-propoxysilane, methyltri-iso-propoxysilane, methyltri-n-butoxysilane, methyltri-sec-butoxysilane, methyltri-tert-butoxysilane, methyltriphenoxysilane, methyltriacetoxysilane, methyltrichlorosilane, methyltriisopropenoxysilane, methyltris(dimethylsiloxy)silane, methyltris(methoxyethoxy)silane, methyltris(methylethylketoxime)silane, methyltris(trimethylsiloxy)silane, methylsilane, ethyltrimethoxysilane, ethyltriethoxysilane, ethyltri-n-propoxysilane, ethyltri-iso-propoxysilane, ethyltri-n-butoxysilane, ethyltri-sec-butoxysilane, ethyltri-tert-butoxysilane, ethyltriphenoxysilane, ethylbistris(trimethylsiloxy)silane, ethyldichlorosilane, ethyltriacetoxysilane, ethyltrichlorosilane, n-propyltrimethoxysilane, n-propyltriethoxysilane, n-propyltri-n-propoxysilane, n-propyltriisopropoxysilane, n-propyltri-n-butoxysilane, n-propyltri-sec-butoxysilane, n-propyltri-tert-butoxysilane, n-propyltriphenoxysilane, n-propyltriacetoxysilane, n-propyltrichlorosilane, iso-propyltrimethoxysilane, iso-propyltriethoxysilane, iso-propyltri-n-propoxysilane, iso-propyltriisopropoxysilane, iso-propyltri-n-butoxysilane, iso-propyltri-sec-butoxysilane, iso-propyltri-tert-butoxysilane, iso-propyltriphenoxysilane, n-butyltrimethoxysilane, n-butyltriethoxysilane, n-butyltri-n-propoxysilane, n-butyltri-iso-propoxysilane, n-butyltri-n-butoxysilane, n-butyltri-sec-butoxysilane, n-butyltri-tert-butoxysilane, n-butyltriphenoxysilane, n-butyltrichlorosilane, 2-methylpropyltrimethoxysilane, 2-methylpropyltriethoxysilane, 2-methylpropyltri-n-propoxysilane, 2-methylpropyltri-iso-propoxysilane, 2-methylpropyltri-n-butoxysilane, 2-methylpropyltri-sec-butoxysilane, 2-methylpropyltri-tert-butoxysilane, 2-methylpropyltriphenoxysilane, 1-methylpropyltrimethoxysilane, 1-methylpropyltriethoxysilane, 1-methylpropyltri-n-propoxysilane, 1-methylpropyltri-iso-propoxysilane, 1-methylpropyltri-n-butoxysilane, 1-methylpropyltri-sec-butoxysilane, 1-methylpropyltri-tert-butoxysilane, 1-methylpropyltriphenoxysilane, tert-butyltrimethoxysilane, tert-butyltriethoxysilane, tert-butyltri-n-propoxysilane, tert-butyltri-iso-propoxysilane, tert-butyltri-n-butoxysilane, tert-butyltri-sec-butoxysilane, tert-butyltri-tert-butoxysilane, tert-butyltriphenoxysilane, tert-butyltrichlorosilane, and tert-butyldichlorosilane; alkenyltrialkoxysilanes such as vinyltrimethoxysilane, vinyltriethoxysilane, vinyltri-n-propoxysilane, vinyltri-iso-propoxysilane, vinyltriphenoxysilane, vinyltri-n-butoxysilane, vinyltri-sec-butoxysilane, vinyltri-tert-butoxysilane, allyltrimethoxysilane, allyltriethoxysilane, allyltri-n-propoxysilane, allyltri-iso-propoxysilane, allyltri-n-butoxysilane, allyltri-sec-butoxysilane, allyltri-tert-butoxysilane, and allyltriphenoxysilane; and the like can be given.

Among these, from the viewpoint of reactivity and easy handling, 4-methylphenyltrimethoxysilane, 4-methoxyphenyltrimethoxysilane, 4-methylbenzyltrimethoxysilane methyltrimethoxysilane, methyltrimethoxysilane, methyltriethoxysilane, methyltri-n-propoxysilane, methyltri-iso-propoxysilane, methyltri-n-butoxysilane, methyltri-sec-butoxysilane, ethyltrimethoxysilane, ethyltriethoxysilane, ethyltri-n-propoxysilane, ethyltri-iso-propoxysilane, ethyltri-n-butoxysilane, ethyltri-sec-butoxysilane, n-propyltrimethoxysilane, n-propyltriethoxysilane, n-propyltri-n-propoxysilane, n-propyltri-iso-propoxysilane, n-propyltri-n-butoxysilane, n-propyltri-sec-butoxysilane, vinyltrimethoxysilane, vinyltriethoxysilane, allyltrimethoxysilane, allyltriethoxysilane, and the like are preferable.

Specific examples of the compound (2) shown by the formula (2) include tetramethoxysilane, tetraethoxysilane, tetra-n-propoxysilane, tetra-iso-propoxysilane, tetra-n-butoxysilane, tetra-sec-butoxysilane, tetra-tert-butoxysilane, tetraphenoxysilane, and tetrachlorosilane.

Among these compounds, tetramethoxysilane and tetraethoxysilane are preferable due to the capability of forming an inverted pattern with excellent dry etching resistance.

In addition to the compound (1) and the compound (2), a hydrolysable silane compound shown by the following formula (ii) (hereinafter may be referred to as “compound (ii)”) may be optionally used as the hydrolysable silane compound to obtain the polysiloxane (A).

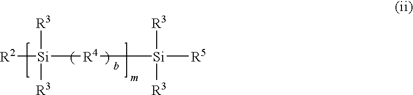

wherein R² and R⁵ individually represent a hydrogen atom, a fluorine atom, an alkoxy group, a linear or branched alkyl group having 1 to 5 carbon atoms, a cyano group, a cyanoalkyl group, or an alkylcarbonyloxy group. R³ individually represent a monovalent organic group, R⁴ represents an arylene group, a methylene group, or an alkylene group having 2 to 10 carbon atoms, and, if plural R⁴ groups exist, the plural R⁴ groups are either same or different, b is an integer from 1 to 3, and m is an integer from 1 to 20.

Examples of an alkoxy group represented by R² and R⁵ in the formula (ii) include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, and the like.

As a linear or branched alkyl group having 1 to 5 carbon atoms, a methyl group, an ethyl group, a propyl group, a butyl group, and the like may be given. One or more hydrogen atoms in these alkyl groups may be substituted with a fluorine atom or the like.

As examples of cyanoalkyl groups, a cyanoethyl group and a cyanopropyl group can be given.

As examples of alkylcarbonyloxy groups, a methylcarbonyloxy group, an ethylcarbonyloxy group, a propylcarbonyloxy group, and a butyl carbonyloxy group can be given.

As examples of the monovalent organic group represented by R³ in the formula (ii), an alkyl group, an alkoxy group, an aryl group, and alkenyl group and groups having a cyclic ether structure such as a glycidyl group can be given. Among these, an alkyl group, an alkoxy group, and an aryl group are preferable.

As examples of an alkyl group, a linear or branched alkyl group having 1 to 5 carbon atoms can be given. Specific examples include a methyl group, an ethyl group, a propyl group, and a butyl group. One or more hydrogen atoms in these alkyl groups may be substituted with a fluorine atom or the like.

As examples of an alkoxy group, a linear or branched alkoxy group having 1 to 10 carbon atoms can be given. Specific examples include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, and an n-decyloxy group.

As examples of aryl groups, a phenyl group, a naphthyl group, a methylphenyl group, a benzyl group, a phenethyl group, an ethylphenyl group, a chlorophenyl group, a bromophenyl group, and a fluorophenyl group can be given. Of these, a phenyl group is preferable.

Examples of the alkenyl group include a vinyl group, a 1-propenyl group, a 2-propenyl group (allyl group), a 3-butenyl group, a 3-pentenyl group, and a 3-hexenyl group.

If plural R⁴ groups exist (i.e when m is an integer from 2 to 20), the plural R⁴ groups may be either same or different.

As an arylene group represented by R⁴ in the formula (ii), those having 6 to 10 carbon atoms are preferable. Specific examples include a phenylene group, a naphthylene group, a methyl phenylene, an ethylphenylene, a chlorophenylene group, a bromophenylene group, and a fluorophenylene group.

As examples of an alkylene group having 2 to 10 carbon atoms, an ethylene group, a propylene group, and a butylene group can be given.

b in the formula (ii) is an integer from 1 to 3, and preferably 1 or 2.

m represents an integer from 1 to 20, preferably 5 to 15, and more preferably from 5 to 10.

As examples of the compound (ii), hexamethoxydisilane, hexaethoxydisilane, hexaphenoxydisilane, 1,1,1,2,2-pentamethoxy-2-methyldisilane, 1,1,1,2,2-pentaethoxy-2-methyldisilane, 1,1,1,2,2-pentaphenoxy-2-methyldisilane, 1,1,1,2,2-pentamethoxy-2-ethyldisilane, 1,1,1,2,2-pentaethoxy-2-ethyldisilane, 1,1,1,2,2-pentaphenoxy-2-ethyldisilane, 1,1,1,2,2-pentamethoxy-2-phenyldisilane, 1,1,1,2,2-pentaethoxy-2-phenyldisilane, 1,1,1,2,2-pentaphenoxy-2-phenyldisilane, 1,1,2,2-tetramethoxy-1,2-dimethyldisi lane, 1,1,2,2-tetraethoxy-1,2-dimethyldisilane, 1,1,2,2-tetraphenoxy-1,2-dimethyldisilane, 1,1,2,2-tetramethoxy-1,2-diethyldisilane, 1,1,2,2-tetraethoxy-1,2-diethyldisilane, 1,1,2,2-tetraphenoxy-1,2-diethyldisilane, 1,1,2,2-tetramethoxy-1,2-diphenyldisilane, 1,1,2,2-tetraethoxy-1,2-diphenyldisilane, 1,1,2,2-tetraphenoxy-1,2-diphenyldisilane,

1,1,2-trimethoxy-1,2,2-trimethyldisilane, 1,1,2-triethoxy-1,2,2-trimethyldisilane, 1,1,2-triphenoxy-1,2,2-trimethyldisilane, 1,1,2-trimethoxy-1,2,2-triethyldisilane, 1,1,2-triethoxy-1,2,2-triethyldisilane, 1,1,2-triphenoxy-1,2,2-triethyldisilane, 1,1,2-trimethoxy-1,2,2-triphenyldisilane, 1,1,2-triethoxy-1,2,2-triphenyldisilane, 1,1,2-triphenoxy-1,2,2-triphenyldisilane, 1,2-dimethoxy-1,1,2,2-tetramethyldisilane, 1,2-diethoxy-1,1,2,2-tetramethyldisilane, 1,2-diphenoxy-1,1,2,2-tetramethyldisilane, 1,2-dimethoxy-1,1,2,2-tetraethyldisilane, 1,2-diethoxy-1,1,2,2-tetraethyldisilane, 1,2-diphenoxy-1,1,2,2-tetraethyldisilane, 1,2-dimethoxy-1,1,2,2-tetraphenyldisilane, 1,2-diethoxy-1,1,2,2-tetraphenyldisilane, 1,2-diphenoxy-1,1,2,2-tetraphenyldisilane;
bis(trimethoxysilyl)methane, bis(triethoxysilyl)methane, bis(tri-n-propoxysilyl)methane, bis(tri-iso-propoxysilyl)methane, bis(tri-n-butoxysilyl)methane, bis(tri-sec-butoxysilyl)methane, bis(tri-tert-butoxysilyl)methane, 1,2-bis(trimethoxysilyl)ethane, 1,2-bis(triethoxysilyl)ethane, 1,2-bis(tri-n-propoxysilyl)ethane, 1,2-bis(tri-iso-propoxysilyl)ethane, 1,2-bis(tri-n-butoxysilyl)ethane, 1,2-bis(tri-sec-butoxysilyl)ethane, 1,2-bis(tri-tert-butoxysily)ethane, 1-(dimethoxymethylsilyl)-1-(trimethoxysilyl)methane, 1-(diethoxymethylsilyl)-1-(triethoxysilyl)methane, 1-(di-n-propoxymethylsilyl)-1-(tri-n-propoxysilyl)methane, 1-(di-iso-propoxymethylsilyl)-1-(tri-iso-propoxysilyl)methane, 1-(di-n-butoxymethylsilyl)-1-(tri-n-butoxysilyl)methane, 1-(di-sec-butoxymethylsilyl)-1-(tri-sec-butoxysilyl)methane, 1-(di-tert-butoxymethylsilyl)-1-(tri-tert-butoxysilyl)methane, 1-(dimethoxymethylsilyl)-2-(trimethoxysilyl)ethane, 1-(diethoxymethylsilyl)-2-(triethoxysilyl)ethane, 1-(di-n-propoxymethylsilyl)-2-(tri-n-propoxysilyl)ethane, 1-(di-iso-propoxymethylsilyl)-2-(tri-iso-propoxysilyl)ethane, 1-(di-n-butoxymethylsilyl)-2-(tri-n-butoxysilyl)ethane, 1-(di-sec-butoxymethylsilyl)-2-(tri-sec-butoxysilyl)ethane, 1-(di-tert-butoxymethylsilyl)-2-(tri-tert-butoxysilyl)ethane,
bis(dimethoxymethylsilyl)methane, bis(diethoxymethylsilyl)methane, bis(di-n-propoxymethylsilyl)methane, bis(di-iso-propoxymethylsilyl)methane, bis(di-n-butoxymethylsilyl)methane, bis(di-sec-butoxymethylsilyl)methane, bis(di-tert-butoxymethylsilyl)methane, 1,2-bis(dimethoxymethylsilyl)ethane, 1,2-bis(diethoxymethylsilyl)ethane, 1,2-bis(di-n-propoxymethylsilyl)ethane, 1,2-bis(di-iso-propoxymethylsilyl)ethane, 1,2-bis(di-n-butoxymethylsilyl)ethane, 1,2-bis(di-sec-butoxymethylsilyl)ethane, 1,2-bis(di-tert-butoxymethylsilyl)ethane, bis(dimethylmethoxysilyl)methane, bis(dimethylethoxysilyl)methane, bis(dimethyl-n-propoxysilyl)methane, bis(dimethyl-iso-propoxysilyl)methane, bis(dimethyl-n-butoxysilyl)methane, bis(dimethyl-sec-butoxysilyl)methane, bis(dimethyl-tert-butoxysilyl)methane, 1,2-bis(dimethylmethoxysilyl)ethane, 1,2-bis(dimethylethoxysilyl)ethane, 1,2-bis(dimethyl-n-propoxysilyl)ethane, 1,2-bis(dimethyl-iso-propoxysilyl)ethane, 1,2-bis(dimethyl-n-butoxysilyl)ethane, 1,2-bis(dimethyl-sec-butoxysilyl)ethane, 1,2-bis(dimethyl-tert-butoxysilyl)ethane,
1-(dimethoxymethylsilyl)-1-(trimethylsilyl)methane, 1-(diethoxymethylsilyl)-1-(trimethylsilyl)methane, 1-(di-n-propoxymethylsilyl)-1-(trimethylsilyl)methane, 1-(di-iso-propoxymethylsilyl)-1-(trimethylsilyl)methane, 1-(di-n-butoxymethylsilyl)-1-(trimethylsilyl)methane, 1-(di-sec-butoxymethylsilyl)-1-(trimethylsilyl)methane, 1-(di-tert-butoxymethylsilyl)-1-(trimethylsilyl)methane, 1-(dimethoxymethylsilyl)-2-(trimethylsilyl)ethane, 1-(diethoxymethylsilyl)-2-(trimethylsilyl)ethane, 1-(di-n-propoxymethylsilyl)-2-(trimethylsilyl)ethane, 1-(di-iso-propoxymethylsilyl)-2-(trimethylsilyl)ethane, 1-(di-n-butoxymethylsilyl)-2-(trimethylsilyl)ethane, 1-(di-sec-butoxymethylsilyl)-2-(trimethylsilyl)ethane, 1-(di-tert-butoxymethylsilyl)-2-(trimethylsilyl)ethane,
1,2-bis(trimethoxysilyl)benzene, 1,2-bis(triethoxysilyl)benzene, 1,2-bis(tri-n-propoxysilyl)benzene, 1,2-bis(tri-iso-propoxysilyl)benzene, 1,2-bis(tri-n-butoxysilyl)benzene, 1,2-bis(tri-sec-butoxysilyl)benzene, 1,2-bis(tri-tert-butoxysilyl)benzene, 1,3-bis(trimethoxysilyl)benzene, 1,3-bis(triethoxysilyl)benzene, 1,3-bis(tri-n-propoxysilyl)benzene, 1,3-bis(tri-iso-propoxysilyl)benzene, 1,3-bis(tri-n-butoxysilyl)benzene, 1,3-bis(tri-sec-butoxysilyl)benzene, 1,3-bis(tri-tert-butoxysilyl)benzene, 1,4-bis(trimethoxysilyl)benzene, 1,4-bis(triethoxysilyl)benzene, 1,4-bis(tri-n-propoxysilyl)benzene, 1,4-bis(tri-iso-propoxysilyl)benzene, 1,4-bis(tri-n-butoxysilyl)benzene, 1,4-bis(tri-sec-butoxysilyl)benzene, 1,4-bis(tri-tert-butoxysilyl)benzene, and the like can be given.

Furthermore, polycarbosilanes such as polydimethoxymethylcarbosilane, polydiethoxymethylcarbosilane, and the like can also be given.

Among these compounds, hexamethoxydisilane, hexethoxydisilane, 1,1,2,2-tetra-methoxy-1,2-dimethyldisilane, 1,1,2,2-tetra-ethoxy-1,2-dimethyldisilane, 1,1,2,2-tetra-methoxy-1,2-diphenyldisilane, 1,2-dimethoxy-1,1,2,2-tetramethyldisilane, 1,2-diethoxy-1,1,2,2-tetramethyldisilane, 1,2-dimethoxy-1,1,2,2-tetra-phenyldisilane, 1,2-diethoxy-1,1,2,2-tetra-phenyldisilane, bis(trimethoxysilyl)methane, bis(triethoxysilyl)methane, 1,2-bis(trimethoxysilyl)ethane, 1,2-bis(triethoxysilyl)ethane, 1-(dimethoxymethylsilyl)-1-(trimethoxysilyl)methane, 1-(diethoxymethylsilyl)-1-(triethoxysilyl)methane, 1-(dimethoxymethylsilyl)-2-(trimethoxysilyl)ethane, 1-(diethoxymethylsilyl)-2-(triethoxysilyl)ethane, bis(dimethoxymethylsilyl)methane, bis(diethoxymethylsilyl)methane, 1,2-bis(dimethoxymethylsilyl)ethane, 1,2-bis(diethoxymethylsilyl)ethane, bis(dimethylmethoxysilyl)methane, bis(dimethylethoxysilyl)methane, 1,2-bis(dimethylmethoxysilyl)ethane, 1,2-bis(dimethylethoxysilyl)ethane, 1-(dimethoxymethylsilyl)-1-(trimethylsilyl)methane, 1-(diethoxymethylsilyl)-1-(trimethylsilyl)methane, 1-(dimethoxymethylsilyl)-2-(trimethylsilyl)ethane, 1-(diethoxymethylsilyl)-2-(trimethylsilyl)ethane, 1,2-bis(trimethoxysilyl)benzene, 1,2-bis(triethoxysilyl)benzene, 1,3-bis(trimethoxysilyl)benzene, 1,3-bis(triethoxysilyl)benzene, 1,4-bis(trimethoxysilyl)benzene, 1,4-bis(triethoxysilyl)benzene, dimethoxymethylcarbosilane, polydiethoxymethylcarbosilane, and the like are preferable.

Either one type of compound (ii) may be used or two or more types of compound (ii) may be used in combination.

The resin composition of the present invention may contain only one type of polysiloxane (A) or may contain two or more types of polysiloxane (A).

The polystyrene-reduced weight average molecular weight of polysiloxane (A) determined by size exclusion chromatography is preferably 2,000 to 100,000, more preferably 2,000 to 50,000, and particularly preferably 2,000 to 30,000.

The molecular weight of the polysiloxane (A) in the present invention was measured by gel permeation chromatography (GPC) using monodisperse polystyrene as a standard and using GPC columns (manufactured by Tosoh Corp., G2000HXL×2, G3000HXL×1, G4000HXL×1) at a flow rate of 1.0 ml/minute, using tetrahydrofuran as an eluate, at a column temperature of 40° C.

### (2) Solvent (B)

The solvent (B) is an organic solvent which can dissolve the polysiloxane (A) but cannot dissolve the photoresist pattern previously formed on a substrate. The solvent (B) preferably includes the compound (3).

The compound (3) is an alkyl alcohol having 4 to 10 carbon atoms (compound having a hydrogen atom as R″ in the formula (3)) or an alkyl ether (compound having an alkyl group as R″ in the formula (3)). The total number of carbon atoms possessed by R′ and R″ in the formula (3) is 4 to 10, and preferably 4 to 8.

As specific examples of alkyl alcohols as the compound (3), 1-butanol, 2-butanol, 2-methyl-1-propanol, 2-methyl-2-propanol, 1-pentanol, 2-pentanol, 3-pentanol, 2-ethyl-1-butanol, 2,4-dimethyl-3-pentanol, 4-methyl-2-pentanol, and 3-methyl-2-pentanol can be given. Among these, 1-butanol, 2-butanol, 4-methyl-2-pentanol, 3-methyl-2-pentanol, and 2-methyl-2-propanol are preferable. Examples of alkyl ethers include dipropyl ether, diisopropyl ether, butyl methyl ether, butyl ethyl ether, butyl propyl ether, dibutyl ether, diisobutyl ether, tert-butyl-methyl ether, tert-butyl ethyl ether, tert-butyl propyl ether, di-tert-butyl ether, dipentyl ether, and isoamyl ether. Among these, isoamyl ether and dibutyl ether are preferable.

The compound (3) may be used either individually or in a combination of two or more.

The solvent (B) may be a mixed solvent of the compound (3) and another solvent.

As examples of the other solvents, monohydric alcohols other than the compound (3), polyhydric alcohols, alkyl ethers of polyhydric alcohols, alkyl ether acetates of polyhydric alcohols, ethers other than the compound (3), cyclic ethers, higher hydrocarbons, aromatic hydrocarbons, ketones, esters, fluorine-containing solvents, water, and the like can be given.

As examples of monohydric alcohols other than the compound (3), methanol, ethanol, n-propanol, iso-propanol, phenol, cyclohexanol, methylcyclohexanol, 3,3,5-trimethylcyclohexanol, benzyl alcohol, phenylmethylcarbinol, diacetone alcohol, cresol, and the like can be given.

Examples of the polyhydric alcohols include ethylene glycol and propylene glycol.

Examples of the alkyl ethers of polyhydric alcohols include ethylene glycol monomethyl ether, ethylene glycol monoethyl ether, ethylene glycol dimethyl ether, ethylene glycol diethyl ether, diethylene glycol monomethyl ether, diethylene glycol monoethyl ether, diethylene glycol dimethyl ether, diethylene glycol diethyl ether, diethylene glycol ethyl methyl ether, propylene glycol monomethyl ether, and propylene glycol monoethyl ether.

Examples of the alkyl ether acetates of polyhydric alcohols include ethylene glycol ethyl ether acetate, diethylene glycol ethyl ether acetate, propylene glycol ethyl ether acetate, and propylene glycol monomethyl ether acetate.

As examples of ethers other than the compound (3), dibutyl ether cyclopentyl methyl ether, cyclohexyl methyl ether, cyclopentyl ethyl ether, cyclohexyl ethyl ether, cyclopentyl propyl ether, cyclopentyl-2-propyl ether, cyclohexyl propyl ether, cyclohexyl-2-propyl ether, cyclopentyl butyl ether, cyclopentyl-tert-butyl ether, cyclohexyl butyl ether, and cyclohexyl-tert-butyl ether can be given.

Examples of cyclic ethers include tetrahydrofuran and dioxane. Examples of higher hydrocarbons include decane, dodecane, and undecane. As examples of aromatic hydrocarbons, benzene, toluene, xylene, and the like can be given.

Examples of ketones include acetone, methyl ethyl ketone, methyl isobutyl ketone, cyclohexanone, 4-hydroxy-4-methyl-2-pentanone, and diacetone alcohol.

Examples of esters include ethyl acetate, butyl acetate, ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, and methyl 3-ethoxypropionate.

As examples of a fluorine-containing solvent, perfluoroalkanes or perfluorocycloalkanes such as perfluorohexane and perfluoroheptane; perfluoroalkenes having a double bond in these perfluoroalkanes or perfluorocycloalkanes; perfluoro cyclic ethers such as perfluorotetrahydrofuran, perfluoro(2-butyltetrahydrofuran); perfluorotributylamine, perfluorotetrapentylamine, perfluorotetrahexylamine, and the like can be given.

Among these, monohydric alcohols, ethers, cyclic ethers, alkyl ethers of polyhydric alcohols, alkyl ether acetates of polyhydric alcohol, and higher hydrocarbons are preferable.

The proportion of the other solvents to be added is preferably 30 mass % or less, and more preferably 20 mass % or less of the total amount of solvents used. Addition of 30 mass % or more of the other solvents causes a problem of mixing with the resist.

The resin composition according to an example of the present invention may further include a surfactant, a crosslinking agent, and other additives, in addition to the polysiloxane (A) and the solvent (B).

Although the method for preparing the resin composition of the present invention is not particularly limited, a polysiloxane (A) is first obtained by hydrolyzing and/or condensing a hydrolysable silane compound in an organic solvent in the presence of water and a catalyst. Specifically, the polysiloxane (A) is obtained by dissolving a compound (1), a compound (2), and optionally a compound (ii) in an organic solvent and continuously or intermittently adding water to the solution to effect hydrolysis and/or condensation usually at 0 to 100° C. In this instance, the catalyst may be previously dispersed in the organic solvent or may be dissolved or dispersed in water which is added later.

The proportion of the compound (1) in all hydrolysable silane compounds is preferably 1 to 99 mol %, more preferably 10 to 95 mol %, and particularly preferably 20 to 90 mol %. The proportion of the compound (2) is preferably 1 to 99 mol %, more preferably 5 to 90 mol %, and particularly preferably 10 to 80 mol %. If the compounds (1) and (2) are used in the above proportions, not only the planarization work to expose the upper surface of the resist film by dry etching using a fluorine-containing gas is easy, but also the resin composition exhibits excellent dry etching resistance and excellent storage stability. The proportion of the compound (ii) is preferably 0 to 50 mol %.

The resin composition according to an example of the present invention can be obtained by mixing the resulting polysiloxane (A), the solvent (B), and optionally used other additives. In this instance, the solid content of the polysiloxane (A) is appropriately adjusted in a range, for example, of 1 to 30 mass %, and particularly 1 to 20 mass %.

Any organic solvents generally used for this type of use may be used for synthesizing the polysiloxane (A) without particular limitations. For example, the same type of solvent as the solvent (B) can be given.

As examples of the catalyst, a metal chelate compound, an organic acid, an inorganic acid, an organic base, and an inorganic base can be given. Of these catalysts, a metal chelate compound, an organic acid, and an inorganic acid are preferable.

### (3) Curing Promoter

In addition to the polysiloxane (A) and the solvent (B), the composition according to an example of the present invention may include a curing promoter. As a preferable curing promoter, an acid generating compound which generates an acid either by ultraviolet radiation or heating (hereinafter referred to as “acid generator”) and a base generating compound which generates a base by ultraviolet radiation (hereinafter referred to as “base generator”) can be given. By adding the curing promoter, it is possible to cause curing of polysiloxane filled in the space of a resist pattern to proceed even at a low temperature and thus to alleviate curing conditions. Since curing of the polysiloxane is promoted while suppressing heat deformation of a resist pattern, a transferred shape can be more excellently maintained.

As acid generators, a compound which generates an acid by heating (hereinafter may be referred to as “thermal acid generator”) and a compound which generates an acid by ultraviolet radiation (hereinafter may be referred to as “photo acid generator”) can be given.

The thermal acid generator is a compound that generates an acid when heated usually at 50 to 450° C., and preferably 90 to 350° C. As examples, an onium salt such as a sulfonium salt, a benzothiazolium salt, an ammonium salt, and a phosphonium salt can be given.

As specific examples of sulfonium salts, alkylsulfonium salts such as 4-acetophenyldimethylsulfonium hexafluoroantimonate, 4-acetoxyphenyldimethylsulfonium hexafluoroarsenate, dimethyl-4-(benzyloxycarbonyloxy)phenylsulfonium hexafluoroantimonate, dimethyl-4-(benzoyloxy)phenylsulfonium hexafluoroantimonate, dimethyl-4-(benzoyloxy)phenylsulfonium hexafluoroarsenate, and dimethyl-3-chloro-4-acetoxyphenylsulfonium hexafluoroantimonate; benzylsulfonium salts such as benzyl-4-hydroxyphenylmethylsulfonium hexafluoroantimonate, benzyl-4-hydroxyphenylmethylsulfonium hexafluorophosphate, 4-acetoxyphenylbenzylmethylsulfonium hexafluoroantimonate, benzyl-4-methoxyphenylmethylsulfonium hexafluoroantimonate, benzyl-2-methyl-4-hydroxyphenylmethylsulfonium hexafluoroantimonate, benzyl-3-chloro-4-hydroxyphenylmethylsulfonium hexafluoroarsenate, 4-methoxybenzyl-4-hydroxyphenylmethylsulfonium hexafluorophosphate, benzointosylate, and 2-nitrobenzyltosylate; dibenzylsulfonium salts such as dibenzyl-4-hydroxyphenylsulfonium hexafluoroantimonate, dibenzyl-4-hydroxyphenylsulfonium hexafluorophosphate, 4-acetoxyphenyldibenzylsulfonium hexafluoroantimonate, dibenzyl-4-methoxyphenylsulfonium hexafluoroantimonate, dibenzyl-3-chloro-4-hydroxyphenylsulfonium hexafluoroarsenate, dibenzyl-3-methyl-4-hydroxy-5-tert-butylphenylsulfonium hexafluoroantimonate, and benzyl-4-methoxybenzyl-4-hydroxyphenylsulfonium hexafluorophosphate; substituted benzylsulfonium salts such as p-chlorobenzyl-4-hydroxyphenylmethylsulfonium hexafluoroantimonate, p-nitrobenzyl-4-hydroxyphenylmethylsulfonium hexafluoroantimonate, p-chlorobenzyl-4-hydroxyphenylmethylsulfonium hexafluorophosphate, p-nitrobenzyl-3-methyl-4-hydroxyphenylmethylsulfonium hexafluoroantimonate, 3,5-dichlorobenzyl-4-hydroxyphenylmethylsulfonium hexafluoroantimonate, o-chlorobenzyl-3-chloro-4-hydroxyphenylmethylsulfonium hexafluoroantimonate; and the like can be given.

As specific examples of a benzothiazonium salt, benzylbenzothiazolium salts such as 3-benzylbenzothiazolium hexafluoroantimonate, 3-benzylbenzothiazolium hexafluorophosphate, 3-benzylbenzothiazolium tetrafluoroborate, 3-(p-methoxybenzyl)benzothiazolium hexafluoroantimonate, 3-benzyl-2-methylthiobenzothiazolium hexafluoroantimonate, and 3-benzyl-5-chlorobenzothiazolium hexafluoroantimonate can be given.

As an example of a thermal acid generator other than those mentioned above, 2,4,4,6-tetrabromocyclohexadienone can be given.

Among the above compounds, 4-acetoxyphenyldimethylsulfonium hexafluoroarsenate, benzyl-4-hydroxyphenylmethylsulfonium hexafluoroantimonate, 4-acetoxyphenylbenzylmethylsulfonium hexafluoroantimonate, dibenzyl-4-hydroxyphenylsulfonium hexafluoroantimonate, 4-acetoxyphenylbenzylsulfonium hexafluoroantimonate, 3-benzylbenzothiazolium hexafluoroantimonate, and the like are preferably used. As examples of commercially available products of these compounds, Sunaide S1-L85, Sunaide S1-L110, Sunaide SI-L145, Sunaide SI-L150, and Sunaide S1-L160 (manufactured by Sanshin Kagaku Kogyo Co., Ltd.), and the like can be given.

The photoacid generator is a compound generating an acid by irradiation of ultraviolet rays at a dose of usually 1 to 100 mJ, and preferably 10 to 50 mJ.

Examples of photoacid generators include onium salt photoacid generators such as diphenyliodonium trifluoromethanesulfonate, diphenyliodonium pyrenesulfonate, diphenyliodonium dodecylbenzenesulfonate, diphenyliodonium nonafluoro-n-butanesulfonate, bis(4-tert-butylphenyl)iodonium trifluoromethanesulfonate, bis(4-tert-butylphenyl)iodonium dodecylbenzenesulfonate, bis(4-tert-butylphenyl)iodonium naphthalenesulfonate, bis(4-tert-butylphenyl)iodonium hexafluoroantimonate, bis(4-tert-butylphenyl)iodonium nonafluoro-n-butanesulfonate, triphenylsulfonium trifluoromethanesulfonate, triphenylsulfonium hexafluoroantimonate, triphenylsulfonium naphthalenesulfonate, triphenylsulfonium nonafluoro-n-butanesulfonate, (hydroxyphenyl)benzenemethylsulfonium toluenesulfonate, cyclohexylmethyl(2-oxocyclohexyl)sulfonium trifluoromethanesulfonate, dicyclohexyl(2-oxocyclohexyl)sulfonium trifluoromethanesulfonate, dimethyl(2-oxocyclohexyl)sulfonium trifluoromethanesulfonate, diphenyliodonium hexafluoroantimonate, triphenylsulfonium camphorsulfonate, (4-hydroxyphenyl)benzylmethylsulfonium toluenesulfonate, 1-paphthyldimethylsulfonium trifluoromethanesulfonate, 1-naphthyldiethylsulfonium trifluoromethanesulfonate, 4-cyano-1-naphthyldimethylsulfonium trifluoromethanesulfonate, 4-nitro-1-naphthyldimethylsulfonium trifluoromethanesulfonate, 4-methyl-1-naphthyldimethylsulfonium trifluoromethanesulfonate, 4-cyano-1-naphthyldiethylsulfonium trifluoromethanesulfonate, 4-nitro-1-naphthyldiethylsulfonium trifluoromethanesulfonate, 4-methyl-1-naphthyldiethylsulfonium trifluoromethanesulfonate, 4-hydroxy-1-naphthyldimethylsulfonium trifluoromethanesulfonate, 4-hydroxy-1-naphthyltetrahydrothiophenium trifluoromethanesulfonate, 4-methoxy-1-naphthyltetrahydrothiophenium trifluoromethanesulfonate, 4-ethoxy-1-naphthyltetrahydrothiophenium trifluoromethanesulfonate, 4-methoxymethoxy-1-naphthyltetrahydrothiophenium trifluoromethanesulfonate, 4-ethoxymethoxy-1-naphthyltetrahydrothiophenium trifluoromethanesulfonate, 4-(1-methoxyethoxy)-1-naphthyltetrahydrothiophenium trifluoromethanesulfonate, 4-(2-methoxyethoxy)-1-naphthyltetrahydrothiophenium trifluoromethanesulfonate, 4-methoxycarbonyloxy-1-naphthyltetrahydrothiophenium trifluoromethanesulfonate, 4-ethoxycarbonyloxy-1-naphthyltetrahydrothiophenium trifluoromethanesulfonate, and 4-n-propoxycarbonyloxy-1-naphthyltetrahydrothiophenium trifluoromethanesulfonate, 4-n-butoxycarbonyloxy-1-naphthyltetrahydrothiophenium trifluoromethanesulfonate, 4-tert-butoxycarbonyloxy-1-naphthyltetrahydrothiophenium trifluoromethanesulfonate, 4-(2-tetrahydrofuranyloxy)-1-naphthyltetrahydrothiophenium trifluoromethanesulfonate, 4-(2-tetrahydropyranyloxy)-1-naphthyltetrahydrothiophenium trifluoromethanesulfonate, 4-benzyloxy-1-naphthyltetrahydrothiophenium trifluoromethanesulfonate, and 1-(naphthylacetomethyl)tetrahydrothiophenium trifluoromethanesulfonate; halogen-containing photoacid generators such as phenylbis(trichloromethyl)-s-triazine, methoxyphenylbis(trichloromethyl)-s-triazine, and naphthylbis(trichloromethyl)-s-triazine;

diazoketone compound photoacid generators such as 1,2-naphthoquinonediazide-4-sulfonylchloride, 1,2-naphthoquinonediazide-5-sulfonylchloride, and 1,2-naphthoquinonediazide-4-sulfonate or 1,2-naphthoquinonediazide-5-sulfonate of 2,3,4,4′-tetrabenzophenone; and sulfonic acid compound photoacid generators such as 4-trisphenacylsulfone, mesitylphenacylsulfone, bis(phenylsulfonyl)methane; benzointosylate, pyrogallol tris(trifluoromethanesulfonate), nitrobenzyl-9,10-diethoxyanthracene-2-sulfonate, trifluoromethanesulfonylbicyclo[2,2,1]hept-5-ene-2,3-dicarbodiimide, N-hydroxysuccinimido trifluoromethanesulfonate, and 1,8-naphthalenedicarboxylic acid imide trifluoromethanesulfonate.

These acid generators may be used either individually or in a combination of two or more.

The amount of the acid generator is preferably 0.1 to 10 parts by mass, and more preferably 0.1 to 5 parts by mass for 100 parts by mass of the solid components of the polysiloxane (A).

Although not particularly limited, a triphenylsulfonium compound, triphenylmethanol; an optically active carbamate such as benzyl carbamate and benzoin carbamate; an amide such as o-carbamoylhydroxylamide, o-carbamoyloxime, an aromatic sulfonamide, α-lactam, and N-(2-allylethynyl)amide; an oxime ester, α-aminoacetophenone, a cobalt complex, and the like can be given as examples of a base generator.

Among these photobase generators, photobase generator (F1) shown by the following formula (f1), or carbamate photobase generator (F2) selected from 2-nitrobenzylcyclohexylcarbamate, [[(2,6-dinitrobenzyl)oxy]carbonyl]cyclohexylamine, N-(2-nitrobenzyloxycarbonyl)pyrrolidine, and bis[[(2-nitrobenzyl)oxy]carbonyl]hexane-1,6-diamine; triphenylmethanol, o-carbamoylhydroxylamide, o-carbamoyloxime, 4-(methylthiobenzoyl)-1-methyl-1-morpholinoethane, (4-morpholinobenzoyl)-1-benzyl-1-dimethylaminopropane, 2-benzyl-2-dimethylamino-1-(4-morpholinophenyl)-butanone, and hexamine cobalt (III) tris(triphenylmethyl borate) are preferably used, with the photobase generator (F1) and photobase generator (F2), particularly the photobase generator (F1) being more preferable.

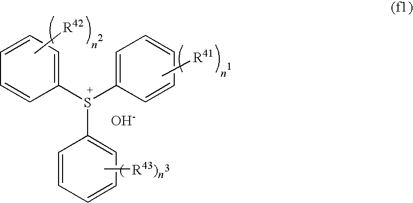

wherein R⁴¹ to R⁴³ individually represent an alkyl group, an alkoxy group, or a halogen atom, and n¹ to n³ individually represent an integer from 0 to 3.

As an alkyl group represented by R⁴¹ to R⁴³, an alkyl group having 1 to 5 carbon atoms is preferable. Among these, a linear or branched alkyl group is more preferable, with a methyl group, an ethyl group, a propyl group, an n-butyl group, and tert-butyl group being particularly preferable.

As an alkoxy group, an alkoxy group having 1 to 5 carbon atoms is preferable. Among these, a linear or branched alkoxy group is more preferable, with a methoxy group and an ethoxy group being particularly preferable.

As a halogen atom, a fluorine atom, chlorine atom, bromine atom, or iodine atom can be given, with a fluorine atom being most preferable.

n¹ to n³ in the formula (f1) individually represent an integer from 0 to 3, and preferably 0 or 1. A compound of the formula (f1) having 0 for all of n¹ to n³ is most preferable.

As a specific preferable example of the base generator (F1), a compound shown by the following formula (f1-1) can be given.

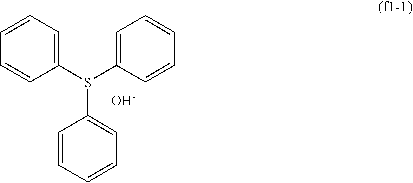

Among the photobase generators (F2), 2-nitrobenzylcyclohexylcarbamate is most preferable from the viewpoint of the effect of the present invention.

These photobase generators may be used either individually or in a combination of two or more.

The amount of the photobase generator is preferably 0.1 to 10 parts by mass, and more preferably 0.1 to 5 parts by mass for 100 parts by mass of the solid components of the polysiloxane (A).

The inverted pattern forming method according to an example of the present invention can excellently fill the space defined by a resist pattern formed on a substrate with the resin composition according to an example of the present invention without mixing with the resist resin. Moreover, the resin composition exhibits excellent dry etching resistance and storage stability. Therefore, the method and the composition of the present invention may be suitable for manufacturing LSIs, particularly for forming fine contact holes which will become more and more minute in the future.

### EXAMPLES

The present invention is described below in more detail by examples. However, these examples should not be construed as limiting the present invention. In the examples, “part” and “%” respectively refer to “part by mass” and “mass %”, unless otherwise indicated.

### [1] Synthesis of Polysiloxane

Polysiloxanes were synthesized as shown in the following Synthesis Examples and Comparative Synthesis Examples. The weight average molecular weight (Mw) of the polysiloxane obtained in each synthesis example was measured by the following method.

### <Measurement of Weight Average Molecular Weight (Mw)>

Mw and Mn were measured by gel permeation chromatography (GPC) using monodisperse polystyrene as a standard and using GPC columns (manufactured by Tosoh Corp., G2000HXL×2, G3000HXL×1, G4000HXL×1) at a flow rate of 1.0 mL/minute, using tetrahydrofuran as an eluate, at a column temperature of 40° C.

### Synthesis Example 1

A three-necked quartz flask was charged with 0.53 g of a 20% maleic acid aqueous solution and 34.89 g of ultrapure water, and the mixture was heated to 65° C. Then, a mixed solution of 6.42 g of tetramethoxysilane, 51.68 g of methyltrimethoxysilane, and 6.48 g of propylene glycol monoethyl ether was added dropwise over one hour, and the mixture was stirred at 65° C. for four hours. The reaction solution was allowed to cool to room temperature and concentrated under reduced pressure to a solid concentration of 25% to obtain a reaction solution (Polysiloxane No. 1). The Mw of the resulting product was 8200.

### Synthesis Example 2

A three-necked quartz flask was charged with 0.54 g of a 20% maleic acid aqueous solution and 35.25 g of ultrapure water, and the mixture was heated to 55° C. Then, a mixed solution of 28.72 g of tetramethoxysilane, 25.70 g of methyltrimethoxysilane, and 9.79 g of propylene glycol monopropyl ether was added dropwise over one hour, and the mixture was stirred at 55° C. for three hours. The reaction solution was allowed to cool to room temperature and concentrated under reduced pressure to a solid concentration of 25% to obtain a reaction solution (Polysiloxane No. 2). The Mw of the resulting product was 10,000.

### Synthesis Example 3

A three-necked quartz flask was charged with 0.54 g of a 20% maleic acid aqueous solution and 35.25 g of ultrapure water, and the mixture was heated to 55° C. Then, a mixed solution of 49.58 g of tetramethoxysilane, 4.93 g of methyltrimethoxysilane, and 7.24 g of propylene glycol monoethyl ether was added dropwise over one hour, and the mixture was stirred at 55° C. for three hours. The reaction solution was allowed to cool to room temperature and concentrated under reduced pressure to a solid concentration of 25% to obtain a reaction solution (Polysiloxane No. 3). The Mw of the resulting product was 12,000.

### Synthesis Example 4

A three-necked quartz flask was charged with 0.54 g of a 20% maleic acid aqueous solution and 35.25 g of ultrapure water, and the mixture was heated to 55° C. Then, a mixed solution of 55.34 g of trichlorosilane, 4.93 g of methyltrimethoxysilane, 3.62 g of methanol, and 3.62 g of propylene glycol monoethyl ether was added dropwise over one hour, and the mixture was stirred at 55° C. for three hours. The reaction solution was allowed to cool to room temperature and concentrated under reduced pressure to a solid concentration of 25% to obtain a reaction solution (Polysiloxane No. 4). The Mw of the resulting product was 12,000.

### Synthesis Example 5

A three-necked quartz flask was charged with 0.46 g of a 20% maleic acid aqueous solution and 29.78 g of ultrapure water, and the mixture was heated to 55° C. Then, a mixed solution of 3.38 g of tetramethoxysilane, 12.11 g of methyltrimethoxysilane, 39.41 g of bistriethoxysilylethane, and 17.38 g of propylene glycol monoethyl ether was added dropwise over one hour, and the mixture was stirred at 55° C. for two hours. The reaction solution was allowed to cool to room temperature and concentrated under reduced pressure to a solid concentration of 25% to obtain a reaction solution (Polysiloxane No. 5). The Mw of the resulting product was 4000.

### Synthesis Example 6

0.42 g of maleic anhydride was dissolved in 2 g of water while heating to obtain an aqueous solution of maleic acid. Next, a flask was charged with 30.5 g of methyltriethoxysilane and 50.8 g of 4-methyl-2-pentanol. The flask was fitted with a condenser and a dropping funnel containing the previously-prepared maleic acid aqueous solution. After heating to 100° C. in an oil bath, the maleic acid aqueous solution was slowly added dropwise, followed by reaction at 100° C. for four hours. The reaction solution was allowed to cool to room temperature and concentrated under reduced pressure to a solid concentration of 25% to obtain a reaction solution (Polysiloxane No. 6). The Mw of the resulting product was 1400.

### Synthesis Example 7

A flask charged with 14.59 g of a 25% tetraammonium hydroxide aqueous solution, 4.53 g of water, and 40.0 g methanol was fitted with a condenser and a dropping funnel containing 10.66 g of tetramethoxysilane, 1.06 g 4-methylphenyltrimethoxysilane, 3.41 g methyltrimethoxysilane, and 50.00 g methanol. After heating to 60° C. on an oil bath, the monomer methanol solution was slowly added dropwise and the mixture was reacted at 60° C. for two hours. After the reaction, the flask containing the reaction solution was allowed to cool.

The resulting reaction solution was added dropwise to a mixed solution of 23.83 g of a 20% maleic anhydride aqueous solution and 18.73 g of methanol, followed by stirring for 30 minutes. Then, after adding 450 g of 4-methyl-2-pentenone, the flask was fitted with an evaporator to remove the reaction solvent and methanol which was produced by the reaction, thereby obtaining a 4-methyl-2-pentenone resin solution. The resulting resin solution was transferred to a separating funnel and washed with 80 g of water, and then 40 g of water. Then, after adding 370 parts of 4-methyl-2-pentanol to the resin solution of 4-methyl-2-pentenone which had been transferred to a flask from the separating funnel, the flask was fitted with an evaporator to remove 4-methyl-2-pentenone to obtain a resin solution (Polysiloxane No. 6).

### [2] Preparation of Resin Composition

Resin compositions were prepared by mixing the polysiloxanes (A) obtained in Synthesis Examples and the curing promoters (C). Solvents (B) were added in amounts to make the solid concentration of each composition as shown in Table 1.

The organic solvents (B) and the curing promoters (C) shown in Table 1 are as follows.

### <(B) Organic Solvent>

B-1: 4-methyl-2-pentanol
B-2: 1-butanol
B-3: dibutyl ether
B-4: isoamyl ether
B-5: propylene glycol monoethyl ether

### <Curing Promoter (C)>

C-1: triphenylsulfonium trifluorosulfonate
C-2: 2-nitrobenzylcyclohexylcarbamate
C-3: 4-acetoxyphenyldimethylsulfonium hexafluoroarsenate

TABLE 1

| | Resin composition No. | | | | | | | | |
|---|---|---|---|---|---|---|---|---|---|
| | 1 | 2 | 3 | 4 | 5 | 6 | 7 | 8 | 9 |
| Solid concentration (%) | 2 | 5 | 2 | 2 | 2 | 2 | 3 | 2 | 2 |
| Polysiloxane (A) (type/part) | No. 1/100 | No. 1/100 | No. 1/100 | No. 2/100 | No. 3/100 | No. 4/100 | No. 5/100 | No. 6/100 | No. 7/100 |
| Curing promoter (C) | — | — | — | — | C-1/1 | C-2/2 | C-3/1 | — | — |
| (type/part) | | | | | | | | | |
| Solvent (B) (type/part) | B-1/100 | B-1/100 | B-1/80 | B-1/100 | B-1/90 | B-2/100 | B-3/90 | B-1/100 | B-1/100 |
| | | | B-5/20 | | B-5/10 | | B-4/10 | | |

### [3] Evaluation of Performance

The performance of each composition was evaluated as follows. The evaluation results are shown in Table 1.

<1> Intermixing with Photoresist Film

A resist composition solution (“AR230JN” manufactured by JSR Corp.) was applied to the surface of a silicon wafer using a spin coater and dried on a hot plate at 126° C. for 90 seconds to form a resist film with a thickness of 170 nm. Each resin composition for pattern inversion was applied to the resist film. After drying on a hot plate at 120° C. for 60 seconds, the resist film thickness was measured using a spectroscopic ellipsometer.

For evaluating intermixing with the photoresist film, a case where the difference between the measured thickness and the initial thickness was less than 50 angstrom was rated as “Good” and a case where the thickness difference was 50 angstrom or more was rated as “Bad”.

### <2> Resist Pattern Filling Properties

A composition for forming an antireflection film (“ARC29” manufactured by Nissan Chemical Industries, Ltd.) was applied to the surface of a silicon wafer using a spin coater and dried on a hot plate at 205° C. for one minute to form an antireflection film (resist underlayer film) with a thickness of 77 nm. The silicon wafer was used as a substrate.

Next, a resist composition (“AR230JN” manufactured by JSR Corp.) was applied to the antireflection film and dried at 126° C. for 90 seconds. In this instance, the resist film thickness was adjusted to 205 nm. The substrate on which the resist film had been formed was irradiated with an ArF excimer laser (wavelength: 193 nm) at a dose of 17 mJ using an ArF excimer laser irradiation device (manufactured by NIKON Corp.) through a quartz mask with a 0.100 μm 1:1 line-and-space pattern. The substrate was then heated at 126° C. for 90 seconds and the resist film was developed using an aqueous solution of 2.38% tetramethylammonium hydroxide for 40 seconds to obtain a 0.100 μm 1:1 line-and-space pattern.

Each resin composition was then applied to the photoresist pattern and the space defined by the pattern by spin coating, and dried on a hot plate at a temperature shown in Table 2 for one minute to form a resin film with a thickness of 150 nm.

For samples of Examples 7 and 9, the entire surface of the wafer was irradiated with an ArF excimer laser (wavelength: 193 nm) at a dose of 50 mJ using an ArF excimer laser exposure device (manufactured by NIKON Corp.) after drying on a hot plate.

The cross-section of each substrate was inspected by a scanning electron microscope (SEM). The resist pattern filling properties were evaluated as “Good” when the resist pattern was filled with the resin composition with no clearance and as “Bad” when there was a void.

In Comparative Example 1, the resist pattern disappeared when the resin composition was applied to the photoresist pattern. In Comparative Example 2, the dry etching resistance was poor due to the failure of the amount of Si and C in the coated film to meet the required range. The storage stability was also poor.

### <3> Dry Etching Resistance

The resin film for pattern inversion formed as mentioned above was subjected to dry etching treatment using a barrel-type oxygen-plasma ashing apparatus (“PR-501” manufactured by Yamato Scientific Co., Ltd.) at 500 W for 15 seconds.

When the thickness difference before and after the treatment of the resin film for pattern inversion was 10 nm or less, the dry etching resistance was evaluated as “Good”, and as “Bad” when it was more than 10 nm.

### <4> Storage Stability

Each resin composition for pattern inversion was applied to the surface of a silicon wafer using a spin coater at 2000 rpm for 20 seconds, and dried on a hot plate at 120° C. for one minute to form a resin film for pattern inversion. The thickness of the resulting film was measured at 9 points using an optical film thickness meter (“UV-1280SE” manufactured by KLA-Tencor), and the average film thickness was determined.

Each resin composition was stored for one week at 40° C., and the resin film was prepared and the thickness measured in the same manner as above. The average thickness was determined in the same manner as above.

The difference (T−T₀) of the average film thickness of the resin film for pattern inversion before storing (T₀) and the average thickness after storing (T) was determined, and the ratio of the difference to the average film thickness, (T−T₀)/T₀, was calculated as the rate of film thickness change. The storage stability was evaluated as “Good” when the rate was 5% or less, and as “Bad” when the rate was more than 5%. A sample producing a gel-like precipitate which can be observed by the visual check was also evaluated as “Bad”.

### <5> Measurement of Proportion of Silicon and Carbon

Each resin composition was applied to the surface of a silicon wafer using a spin coater at 2000 rpm for 20 seconds, and dried on a hot plate at 200° C. for one minute to form a resin film. The silicon content and the carbon content in the resin film in the thickness direction were measured using an SIMS instrument (“PHI ADEPT-1010” manufactured by ULVAC-PHI, Incorporated.). The average value was calculated and used as the Si content or the C content.

TABLE 2

| | Example | | | | | | | | | | | | Comparative |
|---|---|---|---|---|---|---|---|---|---|---|---|---|---|
| | 1 | 2 | 3 | 4 | 5 | 6 | 7 | 8 | 9 | 10 | 11 | 12 | Example |
| Resin composition | 1 | 1 | 2 | 3 | 5 | 6 | 6 | 7 | 7 | 8 | 8 | 10 | 9 |
| Baking temperature/ | 160 | 180 | 120 | 160 | 160 | 140 | 140 | 140 | 140 | 90 | 200 | 180 | 160 |
| ° C. | | | | | | | | | | | | | |
| Exposure dose/mJ/cm² | — | — | — | — | — | — | 50 | — | 50 | — | — | — | — |
| C content/% | 16.3 | — | — | — | 9.5 | 2.1 | — | 2.0 | — | 15.1 | — | 9.93 | 24.1 |
| Si content/% | 42.4 | — | — | — | 44.2 | 46.4 | — | 46.3 | — | 42.6 | — | 43.01 | 28.4 |
| Intermixing with | Good | Good | Good | Good | Good | Good | Good | Good | Good | Good | Good | Good | Good |
| resist film | | | | | | | | | | | | | |
| Resist pattern filling | Good | Good | Good | Good | Good | Good | Good | Good | Good | Good | Good | Good | Good |
| properties | | | | | | | | | | | | | |
| Oxygen ashing | Good | Good | Good | Good | Good | Good | Good | Good | Good | Good | Good | Good | Bad |
| resistance (film | (4.1) | (3.7) | (4.0) | (4.0) | (3.2) | (2.5) | (2.2) | (2.7) | (2.3) | (3.9) | (2.9) | (3.7) | (50) |
| thickness change | | | | | | | | | | | | | |
| width/nm) | | | | | | | | | | | | | |
| Storage stability | Good | Good | Good | Good | Good | Good | Good | Good | Good | Good | Good | Good | Bad |
| (film thickness | (3.5) | (3.5) | (4.7) | (3.2) | (3.9) | (4.3) | (4.2) | (4.2) | (4.1) | (4.2) | (4.1) | (3.2) | (5.2) |
| increase/%) | | | | | | | | | | | | | |

### [4] Inverted Pattern Formation

The method for forming an inverted pattern of Example 1 of the present invention will be described referring to FIG. 1.

A composition for forming an antireflection film (“ARC29” manufactured by Nissan Chemical Industries, Ltd.) was applied to the surface of a silicon wafer using a spin coater and dried on a hot plate at 205° C. for one minute to form an antireflection film (resist underlayer film) with a thickness of 77 nm. The silicon wafer was used as a substrate.

Next, a resist composition (“AR230JN” manufactured by JSR Corp.) was applied to the antireflection film and dried at 126° C. for 90 seconds. In this instance, the resist film thickness was adjusted to 205 nm. The substrate on which the resist film had been formed was exposed to an ArF excimer laser (wavelength: 193 nm) at a dose of 17 mJ using an ArF excimer laser exposure device (manufactured by NIKON Corp.) through a quartz mask with a 0.100 μm 1:1 line-and-space pattern. The substrate was then heated at 126° C. for 90 seconds and the resist film was developed using an aqueous solution of 2.38% tetramethylammonium hydroxide for 40 seconds to obtain a 0.100 μm 1:1 line-and-space pattern on the substrate as shown in FIG. 1(b).

The resin composition for forming an inverted pattern of Example 1 was then applied to the photoresist pattern and the space defined by the pattern using a spin coater at a rotation to form a film with a thickness of 150 nm, and baked at 160° C. for one minute to form a resin film as shown in FIG. 1(c). In this instance, the thickness of the film for forming an inverted pattern was 210 nm.

After that, the surface of the resin film was dry etched using a CF₄/O₂ mixed gas plasma in an RIE apparatus to expose the surface of resist pattern 31 on the surface as shown in FIG. 1(d). In this manner the resin film for forming an inverted pattern was left only in the recessed part of the resist pattern 31 as shown in FIG. 1(d).

What is claimed as new and is desired to be secured by Letters Patent of the United States is:

1. A method for forming an inverted pattern comprising (1) forming a photoresist pattern on a substrate, (2) filling a space formed by the photoresist pattern with a resin composition comprising a polysiloxane and an organic solvent, and (3) removing the photoresist pattern to form an inverted pattern,
the resin composition comprising (A) a polysiloxane obtained by hydrolysis and condensation of a hydrolysable silane compound shown by the following formula (1) and a hydrolysable silane compound shown by the following formula (2), and (B) an organic solvent,
RₐSiX₄₋ₐ (1)
wherein R represents a hydrogen atom, a fluorine atom, a linear or branched alkyl group having 1 to 5 carbon atoms, a cyano group, a cyanoalkyl group, an alkylcarbonyloxy group, an alkenyl group, or an aryl group, X represents a halogen atom or —OR¹ (wherein R¹ represents a monovalent organic group), and a represents an integer from 1 to 3, provided that if a is 2 or 3, the plural R may be either same or different and if 4-a is two or more, the plural X may be either same or different,
SiX₄ (2)
wherein X is the same as defined for the formula (1).

2. The method according to claim 1, wherein the organic solvent (B) comprises a compound shown by the following formula (3),
R′—O—R″ (3)
wherein R′ represents a linear or branched alkyl group having 1 to 10 carbon atoms, and R″ represents a hydrogen atom or a linear or branched alkyl group having 1 to 9 carbon atoms, provided that the total number of carbon atoms contained in R′ and R″ is from 4 to 10.

3. The method according to claim 1, wherein the polysiloxane (A) is obtained by hydrolysis of hydrolysable silane compounds shown by the formulas (1) and (2) in which X represents —OR¹.

4. The method according to claim 1, wherein the inverted pattern has an Si content and a C content measured by the SIMS method of 30 to 46.7 wt % and 1 to 50 wt %, respectively.

5. The method according to claim 1, wherein the step (1) comprises a resist film forming step of applying a resist composition to the substrate and drying the resist composition, an exposure step of applying radiation to a specified area of the resist film, and a development step of developing the exposed areas, the exposure step being carried out two or more times on different areas.

6. The method according to claim 5, wherein the step (1) comprises forming a first resist pattern, and forming a second resist pattern in an area differing from the first resist pattern.

7. The method according to claim 5, wherein the exposure step is repeatedly performed on different areas after the step (1), following which the development step is carried out.

8. A resin composition comprising (A) a polysiloxane obtained by hydrolysis and condensation of a hydrolysable silane compound shown by the following formula (1) and a hydrolysable silane compound shown by the following formula (2), and (B) an organic solvent,
RₐSiX₄₋ₐ (1)
wherein R represents a hydrogen atom, a fluorine atom, a linear or branched alkyl group having 1 to 5 carbon atoms, a cyano group, a cyanoalkyl group, an alkylcarbonyloxy group, an alkenyl group, or an aryl group, X represents a halogen atom or —OR¹ (wherein R¹ represents a monovalent organic group), and a represents an integer from 1 to 3, provided that if a is 2 or 3, the plural R may be either same or different and if 4-a is two or more, the plural X may be either same or different,
SiX₄ (2)
wherein X is the same as defined in the formula (1).

9. The resin composition according to claim 8, wherein the organic solvent (B) comprises a compound shown by the following formula (3),
R′—O—R″ (3)
wherein R′ represents a linear or branched alkyl group having 1 to 10 carbon atoms and R″ represents a hydrogen atom or a linear or branched alkyl group having 1 to 9 carbon atoms, provided that the total number of carbon atoms contained in R′ and R″ is 4 to 10.

10. The resin composition according to claim 8, wherein the polysiloxane (A) has a polystyrene-reduced weight average molecular weight determined by size exclusion chromatography of 2,000 to 100,000.

11. The resin composition according to claim 8, further comprising (C) a curing promoter.
